(19) United States
(12) Patent Application Publication
(10) Pub. No.: US 2018/0286974 A1
(43) Pub. Date: Oct. 4, 2018

(54) SEMICONDUCTOR DEVICE AND MANUFACTURING METHOD THEREOF

(71) Applicants: TOYOTA JIDOSHA KABUSHIKI KAISHA, Toyota-shi, Aichi (JP); DENSO CORPORATION, Kariya-shi, Aichi (JP)

(72) Inventors: Teruaki KUMAZAWA, Toyota-shi (JP); Shinichiro MIYAHARA, Kariya-shi (JP); Sachiko AOI, Nagakute-shi (JP)

(73) Assignees: TOYOTA JIDOSHA KABUSHIKI KAISHA, Toyota-shi, Aichi (JP); DENSO CORPORATION, Kariya-shi, Aichi (JP)

(21) Appl. No.: 15/765,120

(22) PCT Filed: Sep. 16, 2016
(86) PCT No.: PCT/JP2016/004253

§ 371 Date: Mar. 30, 2018

(30) Foreign Application Priority Data
Oct. 19, 2015 (JP) 2015-205759

(51) Int. Cl. H01L 29/78; H01L 29/417; H01L 29/66; H01L 29/739; H01L 23/31; H01L 29/10

(52) U.S. Cl. CPC H01L 29/7813; H01L 29/41741; H01L 29/66734; H01L 29/1095; H01L 23/3192; H01L 29/66068; H01L 29/66348; H01L 29/7397

(57) ABSTRACT

A provided method of manufacturing a semiconductor device includes formation of an interlayer insulating. The interlayer insulating film includes first and second insulating layers. The first insulating layer covers an upper surface of each of the gate electrodes. The second insulating layer is located on the first insulating layer. A contact hole is provided in the interlayer insulating film at a position between the trenches. Then the interlayer insulating film is heated at a temperature lower than the softening temperature of the first insulating layer and higher than the softening temperature of the second insulating layer so as to make a surface of the second insulating layer into a curved surface so that surfaces of end portions of the second insulating layer are sloping from the corresponding contact holes so as to be displaced upward toward a center of the corresponding trench.

### TECHNICAL FIELD

This application claims priority to Japanese Patent Application No. 2015-205759 filed on Oct. 19, 2015, the entire contents of which are hereby incorporated by reference into the present application.

The technique disclosed in this description relates to a semiconductor device and a manufacturing method thereof.

### BACKGROUND ART

Patent Literature 1 discloses a semiconductor device including a plurality of trench type gate electrodes. An upper surface of each of the gate electrodes is covered by an interlayer insulating film (which is herein a BPSG film (Borophosphosilicate Glass)). A contact hole is provided in the interlayer insulating film at positions between two adjacent trenches. An upper electrode layer is provided to cover the interlayer insulating film and the contact holes. The upper electrode layer is connected to a semiconductor substrate within the contact holes. The gate electrodes are insulated from the upper electrode layer by the interlayer insulating film.

In this manufacturing process of the semiconductor device, the interlayer insulating film is formed so as to cover the upper surfaces of the respective gate electrodes and an upper surface of the semiconductor substrate after having formed the trench type gate electrodes. Thereafter, the contact holes are formed in the interlayer insulating film. When the contact holes are formed, steps are created between the upper surface of the interlayer insulating film and bottom surfaces of the contact holes. Next, the interlayer insulating film is softened by heating the interlayer insulating film. Since a softening temperature of the interlayer insulating film (BPSG film) is low, the interlayer insulating film can easily be softened by the heating. Due to this, the surface of the interlayer insulating film is curved, and surfaces of the end portions of the interlayer insulating film (that is, side surfaces of the contact holes) are sloped so as to widen openings of the contact holes. Accordingly, by making the surface of the interlayer insulating film curve, the steps between the upper surface of the interlayer insulating film and the bottom surfaces of the contact holes can be smoothed as compared to prior to the heating. Thereafter, the upper electrode layer is formed so as to cover the interlayer insulating film and the contact holes. Convex and concave patterns are formed on a surface of the upper electrode layer following the shapes of the insulating film and the contact holes. Since the steps between the upper surface of the interlayer insulating film and the bottom surfaces of the contact holes are smoothed by the heating, the concave and convex on the surface of the upper electrode layer are also smoothed.

### CITATION LIST

### Patent Literature

[Patent Literature 1] Japanese Patent Application Publication No. H7-235676

### SUMMARY OF INVENTION

By smoothing the surface of the upper electrode as in the semiconductor device of Patent Literature 1, thermal stress is less likely to be generated in the upper electrode layer. As a result, a crack or the like is less likely to occur in the upper electrode layer, and durability of the semiconductor device in regards to temperature cycles is improved. On the other hand, when the interlayer insulating film is configured by a BPSG film and the interlayer insulating film is deformed so that its surface is curved as in Patent Literature 1, a thickness of the interlayer insulating film becomes thin at its end portions. Since it is difficult to accurately control a shape of the interlayer insulating film upon its deformation, there is a case where the thickness of the interlayer insulating film becomes extremely thin at the end portions of the interlayer insulating film. As a result, a sufficient insulation resistance may not be ensured between the gate electrode and the upper electrode layer in some cases. Thus, in this description, a technique that is capable of obtaining an upper electrode layer having a smoothed surface, and that can sufficiently ensure a thickness of the interlayer insulating film is provided.

A method of manufacturing a semiconductor device is provided herein. The method comprises a trench formation, a gate insulating film formation, a gate electrode formation, an interlayer insulating film formation, a heat treatment, and an upper electrode layer formation. In the trench formation, a plurality of trenches is formed in an upper surface of a semiconductor substrate. In the gate insulating film formation, a gate insulating film is formed in each of the trenches. In the gate electrode formation, a gate electrode insulated from the semiconductor substrate by the gate insulating film is formed in each of the trenches. In the interlayer insulating film formation, an interlayer insulating film including a first insulating layer and a second insulating layer is formed. The first insulating layer covers an upper surface of each of the gate electrodes and the upper surface of the semiconductor substrate. The second insulating layer is located on the first insulating layer and has a softening temperature lower than a softening temperature of the first insulating layer. A contact hole is provided in the interlayer insulating film at a position between each pair of adjacent two of the trenches. In the heat treatment, the interlayer insulating film is heated at a temperature lower than the softening temperature of the first insulating layer and higher than the softening temperature of the second insulating layer so as to make a surface of the second insulating layer into a curved surface so that surfaces of end portions of the second insulating layer are sloping from the corresponding contact holes so as to be displaced upward toward a center of the corresponding trench. In the upper electrode layer formation, an upper electrode layer is formed so as to cover the interlayer insulating film and the contact holes.

Notably, the end portions of the interlayer insulating film refer to portions within the interlayer insulating film that are adjacent to the contact holes. Further, the softening temperature refers to a temperature by which the insulating layer softens to a degree by which it can deform by its own weight and surface tension without any external force. The softening temperature may be a melting temperature. Further, the center of a trench refers to its center in a width direction of the trench (short direction of the trench when the trench is seen from above).

In this manufacturing method, the interlayer insulating film is formed by laminating the second insulating layer having the low softening temperature on the first insulating layer having the high softening temperature. In the heating, the temperature thereof is lower than the softening temperature of the first insulating layer, so the first insulating layer hardly deforms. Further, in the heating, the temperature thereof is higher than the softening temperature of the second insulating layer, so the second insulating layer softens. As a result, the second insulating layer deforms, and the surfaces of the end portions of the second insulating layer slope from the corresponding contact holes so as to be displaced upward toward the center of the corresponding trench (that is, directions separating away from the first insulating layer from the contact holes toward the center of the trench), and the surface of the second insulating layer is curved. Due to this, steps between the upper surface of the interlayer insulating film and bottom surfaces of the contact holes are smoothed as compared to before the heating. Due to this, when the upper electrode layer is formed thereafter, the surface of the upper electrode layer is also smoothed. Further, as described above, since the first insulating layer hardly deforms in the heating, the thickness of the first insulating layer hardly changes. Due to this, even if the second insulating layer deforms and its thickness is locally thinned, a thickness of the interlayer insulating film as a whole can sufficiently be ensured by the first insulating layer. Thus, according to this method, a high insulation resistance can be ensured between the gate electrode and the upper electrode layer.

Further, an novel semiconductor device is provided herein. The semiconductor device comprises a semiconductor substrate, a plurality of trenches provided in an upper surface of the semiconductor substrate, a gate insulating film located in each of the trenches, a gate electrode located in each of the trenches and insulated from the semiconductor substrate by the gate insulating film, an interlayer insulating film including a first insulating layer and a second insulating layer. The first insulating layer covers an upper surface of each of the gate electrodes and the upper surface of the semiconductor substrate. The second insulating layer is located on the first insulating layer and has a softening temperature lower than that of the first insulating layer. A contact hole is provided in the interlayer insulating film at a position between each pair of adjacent two of the trenches. Hte semiconductor device further comprises an upper electrode layer covering the interlayer insulating film and the contact holes. An upper surface of the first insulating layer is flat. A surface of the second insulating layer is curved. Surfaces of end portions of the second insulating layer are sloping from the corresponding contact holes so as to be displaced upward toward a center of the corresponding trench.

According to this semiconductor device, the upper electrode layer having its front surface smoothed can be obtained, and a thickness of the interlayer insulating film can be ensured. A method by which the front surfaces of the second insulating layers are curved is not particularly limited, however, a method that softens and deforms the second insulating layers is suitable.

### BRIEF DESCRIPTION OF DRAWINGS

FIG. 1 is a vertical cross sectional view of a MOSFET 10 of a first embodiment;

FIG. 2 is an explanatory diagram of a method of manufacturing the MOSFET 10 of the first embodiment;

FIG. 3 is an explanatory diagram of the method of manufacturing the MOSFET 10 of the first embodiment;

FIG. 4 is an explanatory diagram of the method of manufacturing the MOSFET 10 of the first embodiment;

FIG. 5 is an explanatory diagram of the method of manufacturing the MOSFET 10 of the first embodiment;

FIG. 6 is an explanatory diagram of the method of manufacturing the MOSFET 10 of the first embodiment;

FIG. 7 is an explanatory diagram of the method of manufacturing the MOSFET 10 of the first embodiment;

FIG. 8 is an explanatory diagram of the method of manufacturing the MOSFET 10 of the first embodiment;

FIG. 9 is an explanatory diagram of the method of manufacturing the MOSFET 10 of the first embodiment;

FIG. 10 is an explanatory diagram of the method of manufacturing the

MOSFET 10 of the first embodiment;

FIG. 11 is an explanatory diagram of the method of manufacturing the MOSFET 10 of the first embodiment;

FIG. 12 is an explanatory diagram of the method of manufacturing the MOSFET 10 of the first embodiment;

FIG. 13 is an explanatory diagram of a manufacturing method for a case of not performing a curved surface processing of second insulating layers 52;

FIG. 14 is an explanatory diagram of the manufacturing method of the MOSFET 10 of the first embodiment;

FIG. 15 is a vertical cross sectional view of a MOSFET of a variant of the first embodiment;

FIG. 16 is a vertical cross sectional view of a MOSFET of a second embodiment;

FIG. 17 is an enlarged cross sectional view of an interlayer insulating film 80 of the MOSFET of the second embodiment;

FIG. 18 is an explanatory diagram of a method of manufacturing the MOSFET of the second embodiment;

FIG. 19 is an explanatory diagram of the method of manufacturing the MOSFET of the second embodiment; and

FIG. 20 is an explanatory diagram of the method of manufacturing the MOSFET of the second embodiment.

### DESCRIPTION OF EMBODIMENTS

### First Embodiment

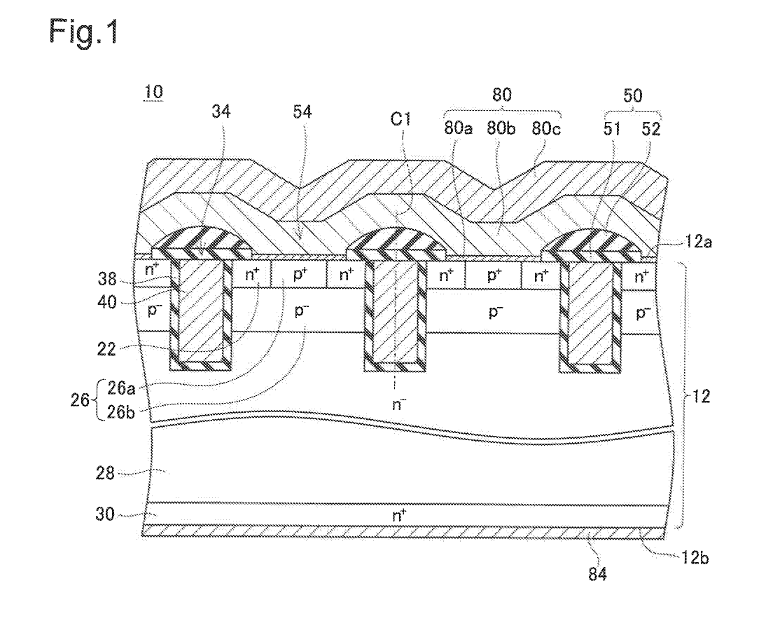

A MOSFET 10 of a first embodiment shown in FIG. 1 comprises a SiC substrate 12 (silicon carbide substrate). A source electrode 80 is provided on an upper surface 12a of the SiC substrate 12. A drain electrode 84 is provided on a lower surface 12b of the SiC substrate 12.

A plurality of trenches 34 is provided in the upper surface 12a of the SiC substrate 12. Each of the trenches 34 extends long along a direction vertical to a sheet surface of FIG. 1. Notably, in FIG. 1, a reference sign C1 denotes a center of a trench 34 in its width direction (left-and-right direction of FIG. 1). A gate insulating film 38 and a gate electrode 40 are provided in each of the trenches 34. Each gate insulating film 38 covers an inner surface of the corresponding trench 34. Each gate electrode 40 is arranged in the corresponding trench 34. The gate electrodes 40 are insulated from the SiC substrate 12 by the gate insulating films 38.

Upper surfaces of the gate electrodes 40 and the upper surface 12a of the SiC substrate 12 are covered by an interlayer insulating film 50. However, a contact hole 54 is provided in the interlayer insulating film 50 at each position between each pair of two adjacent trenches 34. In the contact holes 54, the SiC substrate 12 is not covered by the interlayer insulating film 50.

The interlayer insulating film 50 comprises a first insulating layer 51 and a second insulating layer 52. The first insulating layer 51 is arranged on a SiC substrate 12 side, and the second insulating layer 52 is laminated on the first insulating layer 51.

The first insulating layer 51 covers the upper surfaces of the gate electrodes 40 and the upper surface 12a of the SiC substrate 12 at positions adjacent to the trenches 34. The first insulating layer 51 is constituted of NSG (Non-doped Silicate glass). The first insulating layer 51 has a substantially constant thickness regardless of its positions. An upper surface of the first insulating layer 51 is a flat surface.

The second insulating layer 52 is arranged on the first insulating layer 51. The second insulating layer 52 is constituted of TEOS (Tetraethyl Orthosilicate), PSG (Phospho Silicate Glass), BPSG (Boron Phospho Silicate Glass), or the like. A softening temperature of the second insulating layer 52 is a temperature that is lower than a softening temperature of the first insulating layer 51. A thickness of the second insulating layer 52 is thick above the center C1 of each of the trenches 34 in the width direction, and becomes thinner toward its sides closer to the contact holes 54. An upper surface of the second insulating layer 52 is a curved surface that is bulged in a convex shape.

The aforementioned source electrode 80 covers the interlayer insulating film 50 and the contact holes 54. The source electrode 80 is insulated from the gate electrodes 40 by the interlayer insulating film 50. The source electrode 80 is in contact with the upper surface 12a of the SiC substrate 12 within the contact holes 54. The source electrode 80 comprises contact layers 80a being in contact with the SiC substrate 12, an intermediate layer 80b provided on the contact layers 80a, and a front surface layer 80c provided on the intermediate layer 80b. The contact layers 80a are constituted of NiSi layers (nickel silicide layer). The intermediate layer 80b is constituted primarily of an AlSi layer (aluminum silicide layer). More specifically, the intermediate layer 80b has a laminated structure of a very thin Ti layer (titanium layer) and a thick AlSi layer. The Ti layer is in contact with the interlayer insulating film 50 and the contact layers 80a. The AlSi layer covers substantially an entirety of a front surface of the Ti layer. The front surface layer 80c is constituted primarily of a Ni layer (nickel layer). More specifically, the front surface layer 80c has a laminated structure of a thick Ni layer and a very thin Au layer (gold layer). The Ni layer covers substantially an entirety of a front surface of the intermediate layer 80b. The Au layer covers substantially an entirety of a front surface of the Ni layer.

Source regions 22, a body region 26, a drift region 28, and a drain region 30 are provided in the SiC substrate 12.

The source regions 22 are provided in the SiC substrate 12 in plurality. Each of the source regions 22 is an n-type region. Each of the source regions 22 is provided in a range exposed on the upper surface 12a of the SiC substrate 12. Each of the source regions 22 is in ohmic contact with the source electrode 80 (that is, the corresponding contact layer 80a). Each of the source regions 22 is in contact with the corresponding gate insulating film 38.

The body region 26 is provided on lateral and lower sides of the source regions 22, and is in contact with the source regions 22. The body region 26 is a p-type region, and comprises a plurality of contact regions 26a and a low-concentration body region 26b. A p-type impurity concentration of each of the contact regions 26a is higher than a p-type impurity concentration of the low-concentration body region 26b. Each of the contact regions 26a is provided beside the corresponding source region 22, and is exposed on the upper surface 12a of the SiC substrate 12. Each of the contact regions 26a is in ohmic contact with the source electrode 80 (that is, the corresponding contact layer 80a). The low-concentration body region 26b is provided below the source regions 22 and the contact regions 26a. The low-concentration body region 26b is in contact with the gate insulating films 38 under the source regions 22.

The drift region 28 is an n-type region containing n-type impurities at a low concentration. The n-type impurity concentration of the drift region 28 is lower than an n-type impurity concentration of the source regions 22. The drift region 28 is provided below the low-concentration body region 26b. The drift region 28 spreads from a position at a lower end of the low-concentration body region 26b to a lower side than bottom surfaces of the trenches 34. The drift region 28 is separated from the source regions 22 by the body region 26. The drift region 28 is in contact with the gate insulating films 38 below the low-concentration body region 26b.

The drain region 30 is an n-type region containing n-type impurities at a higher concentration than the drift region 28. The drain region 30 is provided below the drift region 28 and is in contact with the drift region 28. The drain region 30 is provided in a range exposed on the lower surface 12b of the SiC substrate 12. The drain region 30 is in ohmic contact with the drain electrode 84.

Upon using the MOSFET 10, a higher potential is applied to the drain electrode 84 than a potential applied to the source electrode 80. A potential of the gate electrodes 40 is controlled by a control circuit. When a potential that is equal to or higher than a threshold is applied to the gate electrodes 40, the low-concentration body region 26b located at ranges adjacent to the gate insulating films 38 inverts to an n-type, and channels are formed therein. Then, electrons flow from the source electrode 80 toward the drain electrode 84 through the source regions 22, the channels, the drift region 28, and the drain region 30. That is, the MOSFET 10 turns on. When the potential of the gate electrodes 40 is controlled to a potential that is less than the threshold, the channels disappear and the MOSFET 10 turns off.

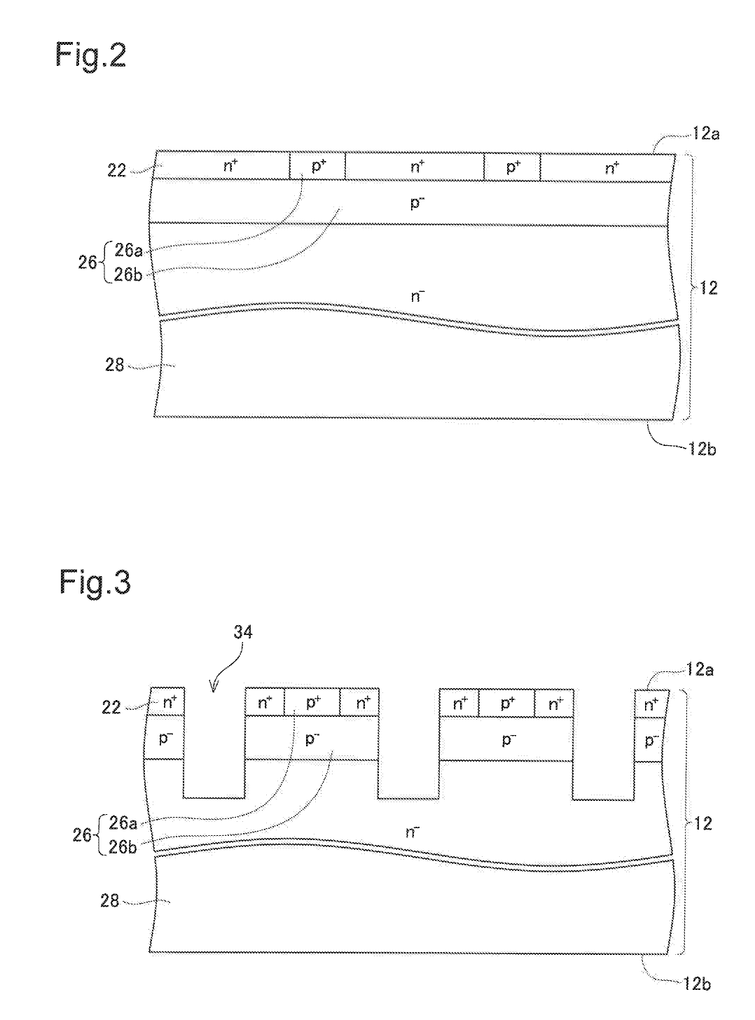

Next, a manufacturing method of the MOSFET 10 will be described. The MOSFET 10 is manufactured from a SiC substrate 12 (SiC substrate 12 that has not yet been processed) constituted of an n-type semiconductor having a low n-type impurity concentration (having an n-type impurity concentration that is substantially equal to that of the drift region 28) over its entirety. Firstly, as shown in FIG. 2, the source regions 22, the contact regions 26a, and the low-concentration body region 26b are formed by ion implantation, epitaxial growth, and the like.

Next, as shown in FIG. 3, the plurality of trenches 34 is formed in the upper surface 12a of the SiC substrate 12. Each of the trenches 34 is formed so as to penetrate the corresponding source region 22 and the low-concentration body region 26b, and reach the drift region 28.

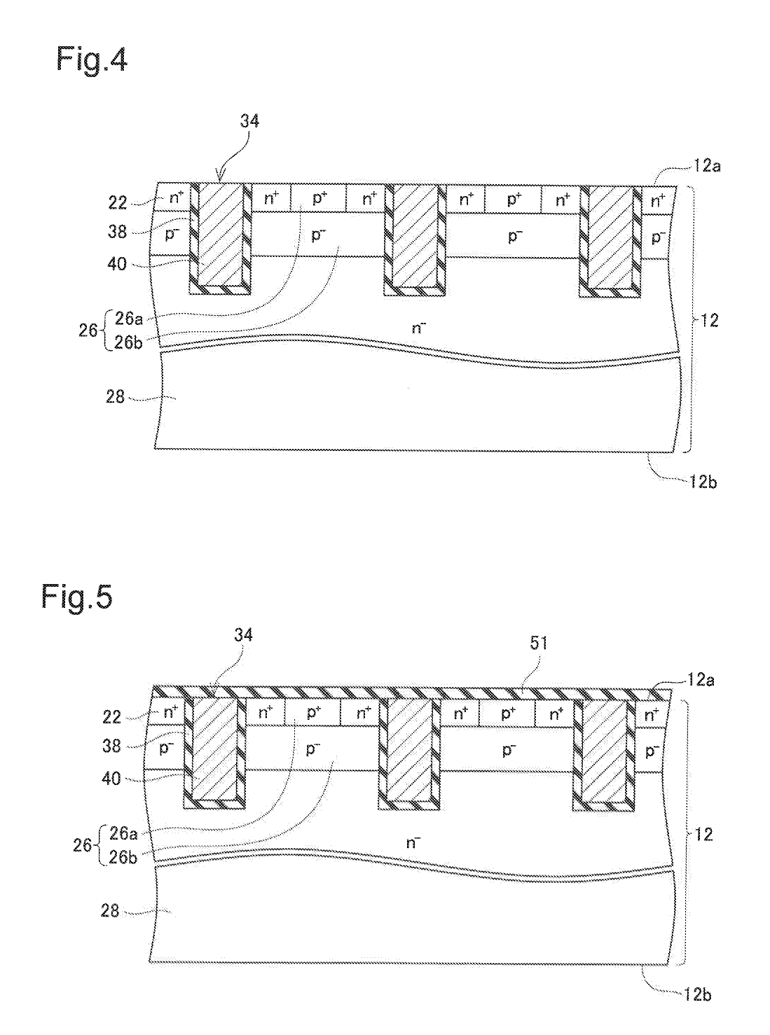

Next, as shown in FIG. 4, the gate insulating films 38 are formed so as to cover the inner surfaces of the trenches 34. Next, as shown in FIG. 4, the gate electrodes 40 are formed inside the trenches 34 having their inner surfaces covered by the gate insulating films 38.

Next, as shown in FIG. 5, the first insulating layer 51 is formed so as to cover the upper surface 12a of the SiC substrate 12 and the upper surfaces of the gate electrodes 40. The first insulating layer 51 is formed by growing NSG on the SiC substrate 12 and the gate electrodes 40 by an atmospheric pressure CVD. The thickness of the first insulating layer 51 is substantially constant, and the upper surface of the first insulating layer 51 is a flat surface.

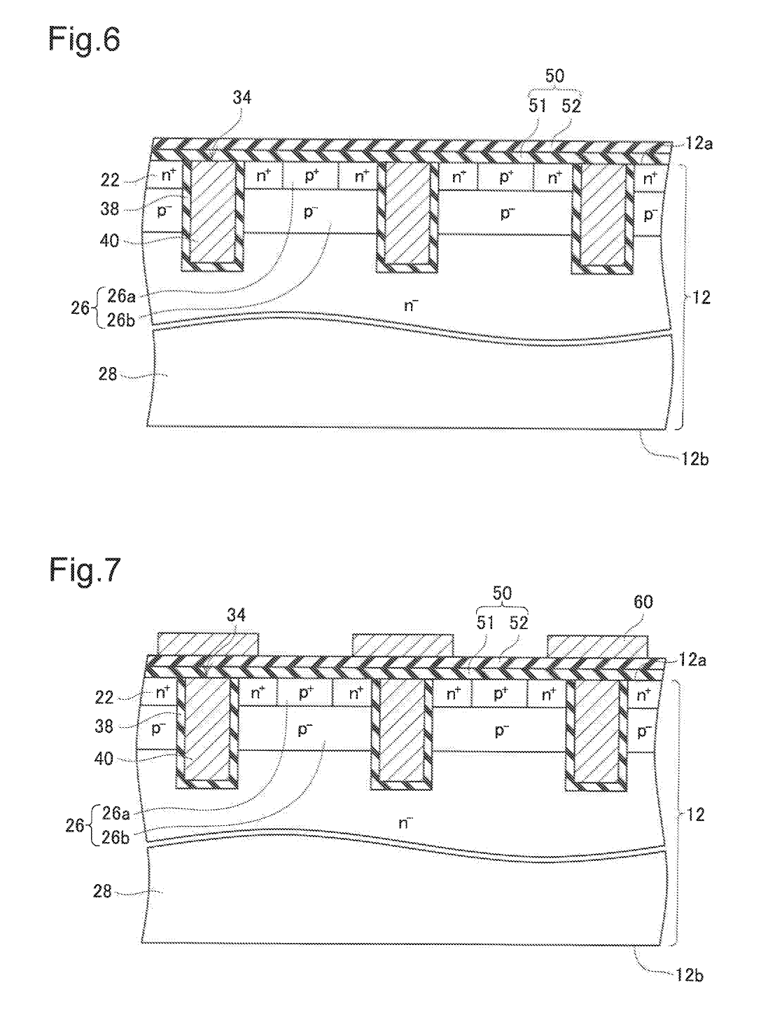

Next, as shown in FIG. 6, the second insulating layer 52 is formed on the upper surface of the first insulating layer 51. The second insulating layer 52 is formed by growing BPSG on the first insulating layer 51 by the atmospheric pressure CVD. At this stage, the thickness of the second insulating layer 52 is substantially constant, and the upper surface of the second insulating layer 52 is a flat surface.

Next, as shown in FIG. 7, a patterned resist 60 is formed on the second insulating layer 52. The resist 60 is formed by forming a resist film over an entirety of the upper surface of the second insulating layer 52 and patterning the resist film by an exposure process and the like. The resist 60 is patterned so that it covers ranges of the interlayer insulating film 50 where the contact holes 54 should not be formed, and does not cover ranges of the interlayer insulating film 50 where the contact holes 54 should be formed. That is, the resist 60 is patterned so that it covers portions above the trenches 34 and their peripheries, and does not cover vicinities of center portions between pairs of adjacent two trenches 34.

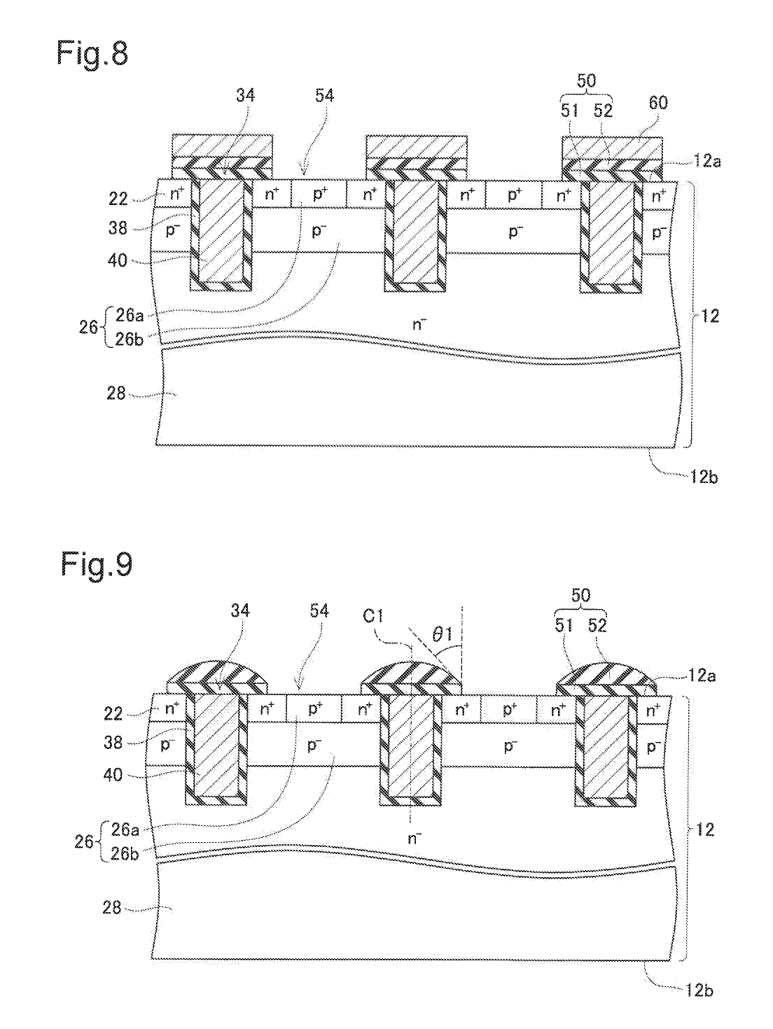

Next, as shown in FIG. 8, the contact holes 54 are formed by etching the interlayer insulating film 50 using the resist 60 as a mask. Here, the interlayer insulating film 50 is etched by anisotropic etching such as RIE. Due to this, at this stage, side surfaces of the contact holes 54 (that is, side surfaces of the first insulating layer 51 and side surfaces of the second insulating layer 52) extend substantially vertical to the upper surface 12a of the SiC substrate 12. That is, steps having a zigzag-pattern cross sectional shape are formed between the upper surface of the interlayer insulating film 50 and bottom surfaces of the contact holes 54. When the contact holes 54 are formed, the resist 60 is removed by ashing and the like.

Next, the SiC substrate 12 is subjected to heating in N₂ atmosphere. Here, the SiC substrate 12 is heated to a temperature that is lower than the softening temperature of the first insulating layer 51 and higher than the softening temperature of the second insulating layer 52. The first insulating layer 51 and the second insulating layer 52 are heated together with the SiC substrate 12. Since the heating temperature is lower than the softening temperature of the first insulating layer 51, the first insulating layer 51 does not soften at this stage, so a shape of the first insulating layer 51 hardly changes. On the other hand, since the heating temperature is higher than the softening temperature of the second insulating layer 52, the second insulating layer 52 hereby softens. As shown in FIG. 9, the softened second insulating layer 52 does not flow to contact hole 54 sides, but remains atop of the first insulating layer 51. Further, a front surface of the softened second insulating layer 52 turns into a curved surface by surface tension. When the front surface of the second insulating layer 52 turns into a curved surface, surfaces of end portions of the second insulating layer 52 (portions closest to the contact holes 54) slope respectively in a direction being displaced upward from the contact holes 54 toward the center of each trench 34 (that is, a direction separating away from the first insulating layer 51 from the contact holes 54 toward the center of each trench 34). That is, an inclination angle θ1 of the surfaces of the end portions of the second insulating layer 52 (more specifically, an angle between a perpendicular line of the upper surface 12a of the SiC substrate 12 and each of the surfaces of the end portions of the second insulating layer 52) increases. That is, the surfaces of the end portions of the second insulating layer 52 (that is, the lateral surfaces) were substantially parallel to the perpendicular line of the upper surface 12a of the SiC substrate 12 before the heating, thus the inclination angle θ1 thereof was substantially 0 degrees. By performing the heating, the surfaces of the end portions of the second insulating layer 52 curve and the inclination angle θ1 increases. Accordingly, the steps between the upper surface of the interlayer insulating film 50 and the bottom surfaces of the contact holes 54 are smoothed out by the second insulating layer 52 deforming into the curved surface while increasing the inclination angle θ1. Thereafter, when the temperature is lowered, the second insulating layer 52 hardens in a state of being curved. Accordingly, the curved second insulating layer 52 as shown in FIG. 9 is obtained.

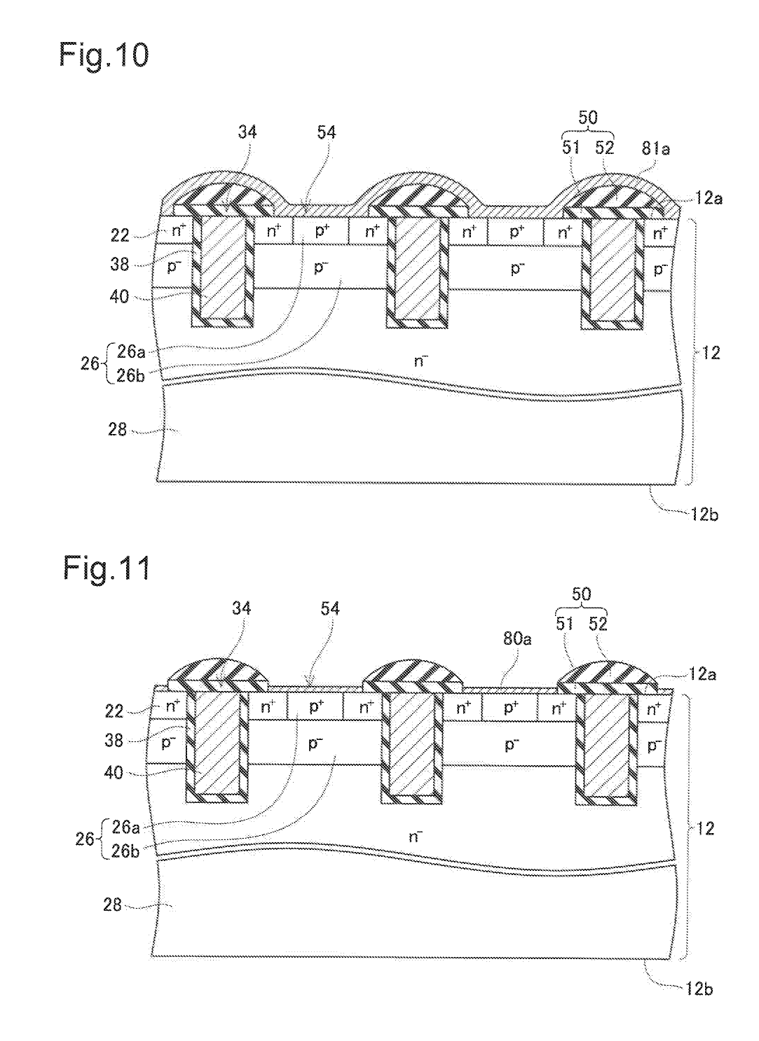

Next, as shown in FIG. 10, a Ni layer 81a is formed so as to cover the interlayer insulating film 50 and the contact holes 54. Notably, instead of the Ni layer 81a, a metal layer of Al, Ti, or Mo and the like may be formed. Next, the SiC substrate 12 is subjected to heating so that the Ni layer 81a and the SiC substrate 12 are caused to react at interfaces between the Ni layer 81a and the SiC substrate 12. Due to this, the Ni layer 81a becomes a silicide at these interfaces as shown in FIG. 11, as a result of which the contact layers 80a (nickel silicide layers) are formed. Notably, in a case of having formed a layer of another metal (Al, Ti, Mo, etc.) instead of the Ni layer 81a, the contact layers 80a in which that metal layer has become a silicide are formed. When the contact layers 80a are formed, the Ni layer 81a (or the metal layer of Al, Ti, Mo, etc.) that covers ranges other than the contact holes 54 are removed by etching as shown in FIG. 11, and thereafter annealing is performed.

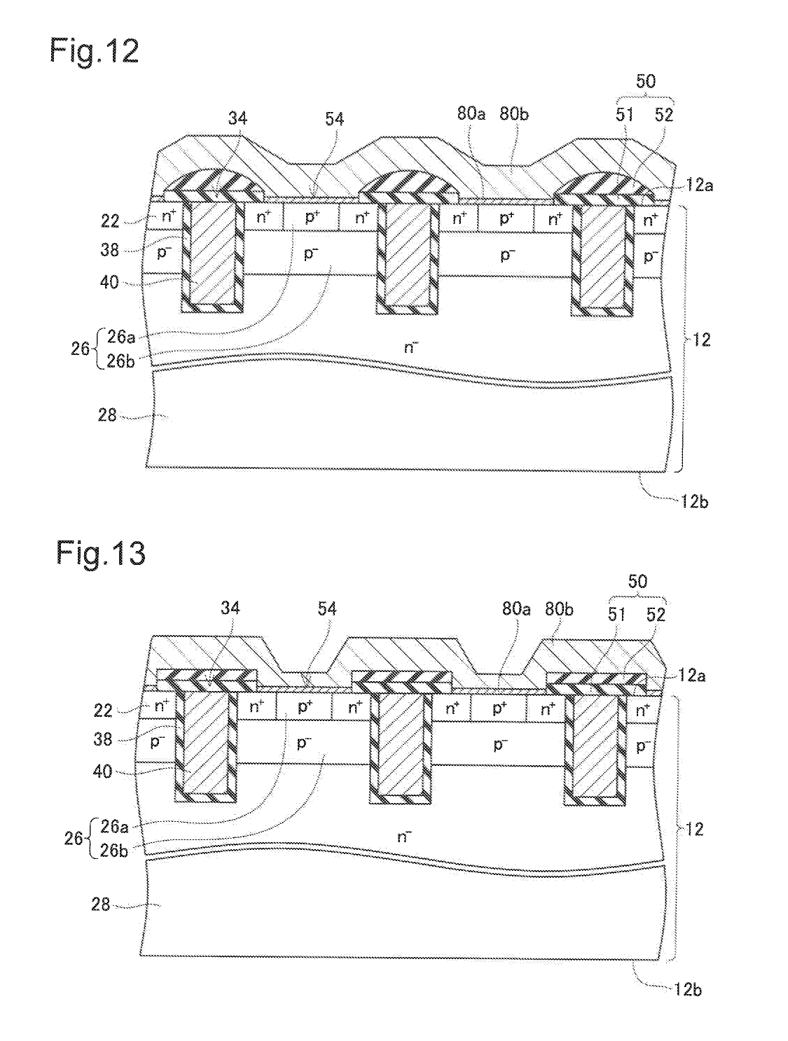

Next, the Ti layer and the AlSi layer are grown in order by sputtering so as to cover the interlayer insulating film 50 and the contact layers 80a. Due to this, the intermediate layer 80b is formed as shown in FIG. 12. Here, the sputtering is performed by controlling a surface temperature to be equal to or less than 500 degrees Celsius. Notably, particles of an electrode material that flies from a sputtering target toward the SiC substrate 12 include not only particles flying along a trajectory vertical to the upper surface 12a of the SiC substrate 12 but also a large number of particles flying obliquely with respect to the upper surface 12a of the SiC substrate 12. In the present embodiment, since the surfaces of the end portions of the second insulating layer 52 are sloped so as to widen a width of openings of the contact holes, the particles flying obliquely with respect to the upper surface 12a can easily enter into the contact holes 54. Due to this, the intermediate layer 80b (that is, Ti layer and AlSi layer) grows effectively in the contact holes 54. Due to this, the intermediate layer 80b is formed over the interlayer insulating film 50 and within the contact holes 54 at substantially a constant film thickness. Further, a front surface of the intermediate layer 80b comes to have a convex and concave surface pattern that follows the shapes of the interlayer insulating film 50 and the contact holes 54. In the present embodiment, the steps between the upper surface of the interlayer insulating film 50 and the bottom surfaces of the contact holes 54 were smoothed out prior to forming the intermediate layer 80b. Due to this, the surface pattern on the front surface of the intermediate layer 80b is also smoothed.

Notably, as shown in FIG. 13, in a case of forming the intermediate layer 80b without forming the curved surface of the second insulating layer 52 by heating (that is, the smoothing of the steps between the upper surface of the interlayer insulating film 50 and the bottom surfaces of the contact holes 54), large concavities and convexities are formed on the front surface of the intermediate layer 80b. Especially, in this case, the intermediate layer 80b cannot easily grow in the contact holes 54 because of a narrow width of the openings of the contact holes 54. Due to this, the thickness of the intermediate layer 80b becomes thinner in the contact holes 54 than on the interlayer insulating film 50. As a result of this, as shown in FIG. 13, large concavities and convexities are formed on the front surface of the intermediate layer 80b. As is apparent by comparing FIGS. 12 and 13, according to the method of the first embodiment, the front surface of the intermediate layer 80b can be smoothed.

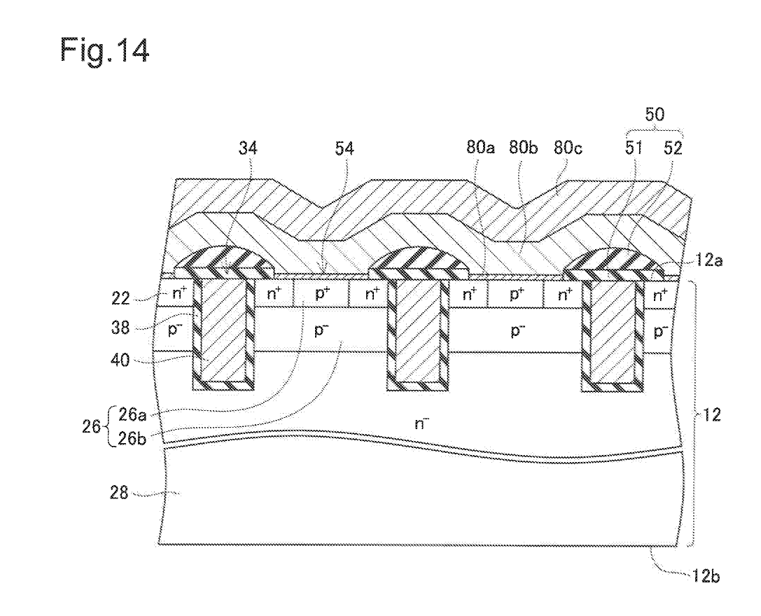

Next, the Ni layer and the Au layer are grown on the intermediate layer 80b by electroless deposition. Due to this, as shown in FIG. 14, the front surface layer 80c is formed. Since the front surface of the intermediate layer 80b is smoothed, a front surface of the front surface layer 80c is also smoothed. Thereafter, by forming structures (that is, the drain region 30 and the drain electrode 84) on a lower surface 12b side using well-known methods, the MOSFET 10 shown in FIG. 1 is completed.

As described above, according to the method of the first embodiment, the intermediate layer 80b and the front surface layer 80c having their front surfaces smoothed can be obtained. Due to this, thermal stress is less likely to occur within the intermediate layer 80b and the front surface layer 80c, so a crack is less likely to occur in the source electrode 80. Thus, durability of the MOSFET 10 in regards to temperature cycles can be improved. Further, according to the method of the first embodiment, the first insulating layer 51 hardly deforms upon deforming the second insulating layer 52 by heating. Due to this, the first insulating layer 51 having the constant thickness is present on top of and around the top of the gate electrodes 40. Thus, the interlayer insulating film 50 does not become extremely thin in the vicinities of the gate electrodes 40. Thus, a sufficient insulation resistance can be ensured between the gate electrodes 40 and the source electrode 80.

Further, according to the method of the first embodiment, the softened second insulating layer 52 does not flow out over edges of the upper surface of the first insulating layer 51, so the softened second insulating layer 52 is suppressed from flowing into the contact hole 54 sides. If the softened second insulating layer 52 flows into the contact holes 54, the width of the contact holes 54 is narrowed, so a desired conductivity performance may not be obtained in the contact holes 54. Contrary to this, in the method of the first embodiment, the softened second insulating layer 52 remains atop of the first insulating layer 51, so the width of the contact holes 54 can be suppressed from becoming narrowed.

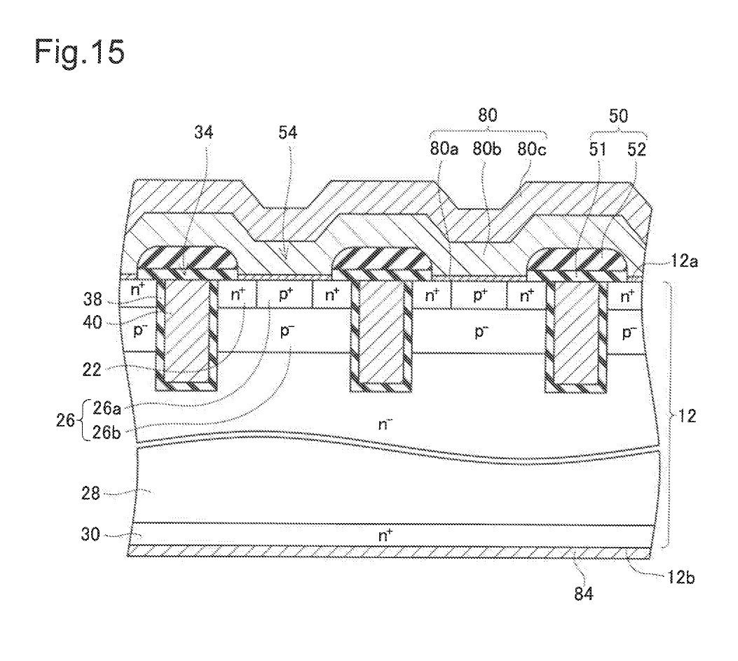

Notably, in the aforementioned first embodiment, an entirety of the front surface of the second insulating layer 52 on the first insulating layer 51 is formed into curved surface. However, as shown in FIG. 15, a flat region may remain on the front surface of the second insulating layer 52. In a case where a viscosity of the softened second insulating layer 52 is high, there is a case where the surfaces of the end portions of the second insulating layer 52 are curved while a surface of a center portion of the second insulating layer 52 remains flat as in FIG. 15. Even in such case, the surfaces of the end portions of the second insulating layer 52 are sloped after the heating. Thus, compared to the case of not performing the softening of the second insulating layer 52 (for example as in the case of FIG. 13), the front surfaces of the intermediate layer 80b and the front surface layer 80c can be smoothed.

### Second Embodiment

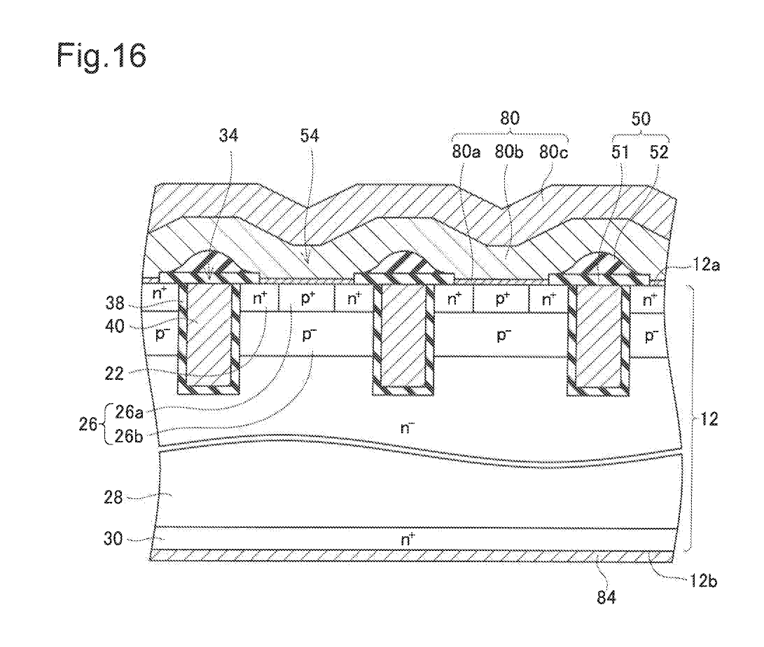

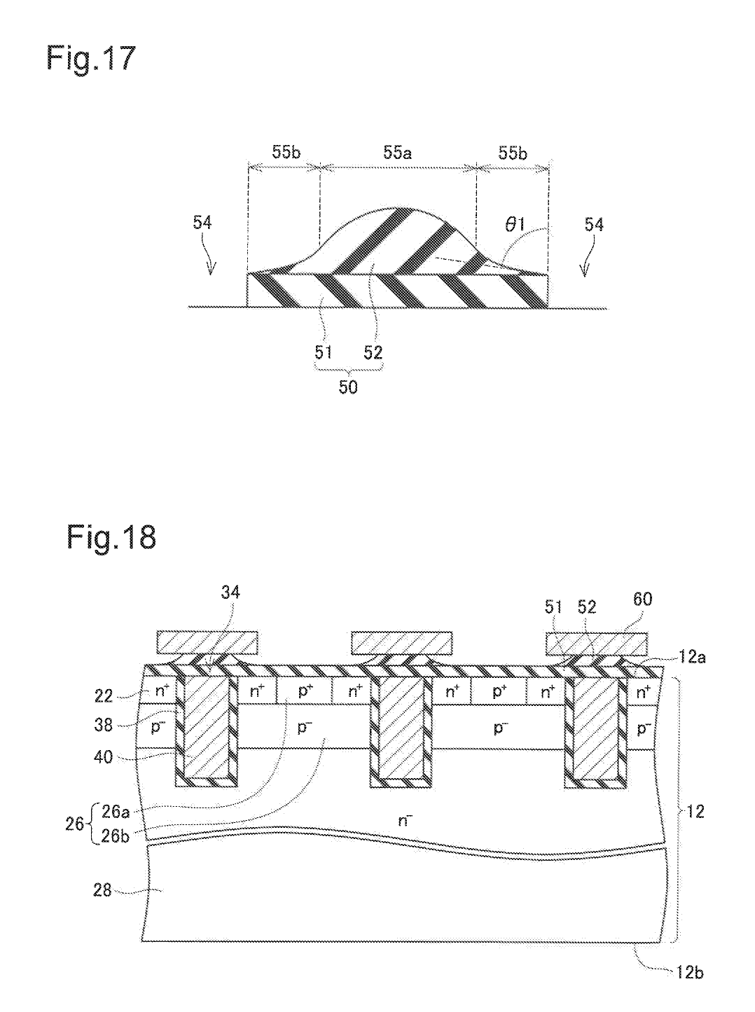

In a semiconductor device of a second embodiment shown in FIG. 16, the shape of the second insulating layer 52 differs from that of the first embodiment. FIG. 17 shows an enlarged cross sectional view of an interlayer insulating film 50 of the second embodiment. In the second embodiment, a surface of each center portion 55a of the second insulating layer 52 has a curved shape that is bulged in a convex shape, whereas surfaces of end portions 55b of the second insulating layer 52 (that is, portions adjacent to the contact holes 54) have a curved shape that is recessed in a concave shape. Due to this, the inclination angle θ1 of the surfaces of the end portions 55b is larger than that of the first embodiment (see FIG. 9). Due to this, in the semiconductor device of the second embodiment, the intermediate layer 80b tends to be formed thick within the contact holes 54, so the front surface of the intermediate layer 80b is further smoothed than in the semiconductor device of the first embodiment (see FIG. 1). Due to this, in the semiconductor device of the second embodiment, the front surface of the front surface layer 80c is further smoothed than in the semiconductor device of the first embodiment. Other configurations of the MOSFET of the second embodiment are similar to those of the MOSFET 10 of the first embodiment.

A manufacturing method of the MOSFET 10 of the second embodiment will be described. The manufacturing method of the MOSFET 10 of the second embodiment is carried out similarly to the manufacturing method of the first embodiment until the process shown in FIG. 7. Then, as shown in FIG. 18, the second insulating layer 52 in openings of the resist 60 is etched by an isotropic etching (for example, CDE (Chemical Dry Etching) and the like). Here, the etching is performed until the first insulating layer 51 is exposed within the openings of the resist 60. Due to the isotropic etching, the etching progresses to a rear side of the resist 60. Due to this, the side surfaces of the second insulating layer 52 come to have a sloped shape in a tapered manner. Accordingly, a width of a surface layer portion of the second insulating layer 52 becomes narrower than a width of the resist 60.

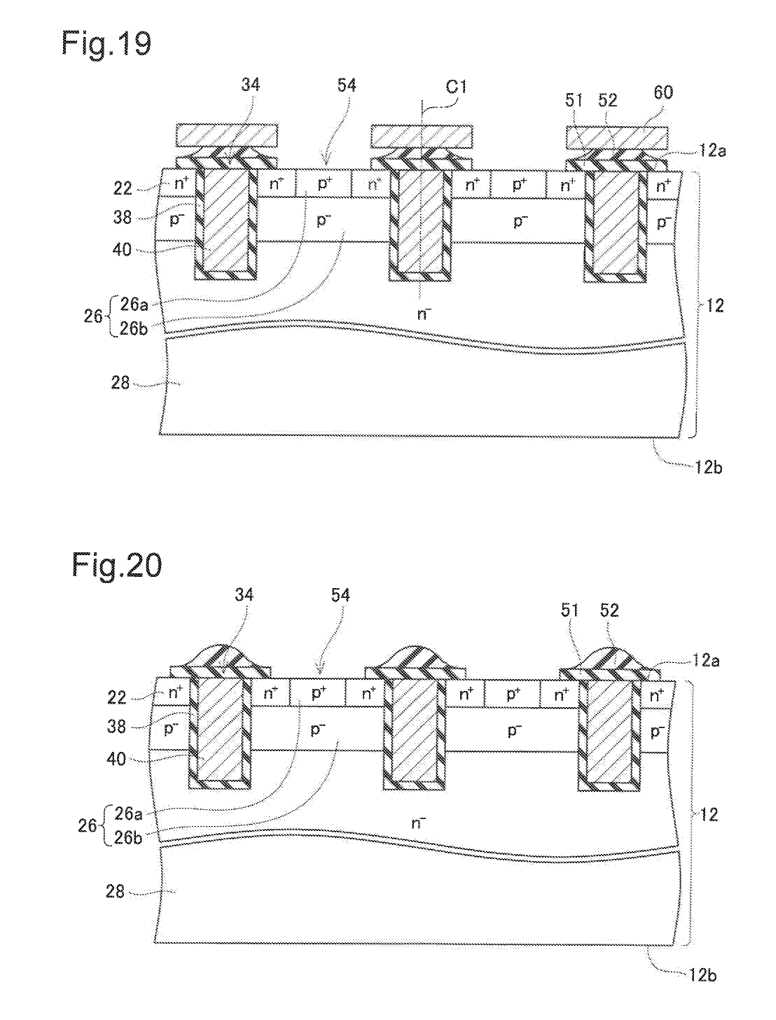

Next, as shown in FIG. 19, the first insulating layer 51 is etched by using the resist 60 as a mask. Due to this, the contact holes 54 are formed. Here, the first insulating layer 51 is etched by an anisotropic etching such as RIE. This etching progresses substantially vertical to the upper surface 12a of the SiC substrate 12. Due to this, the interlayer insulating film 50 is etched over a narrower range than the range of the isotropic etching described in FIG. 18. As shown in FIG. 19, the side surfaces of the first insulating layer 51 become substantially vertical to the upper surface 12a of the SiC substrate 12. On the other hand, as described above, the side surfaces of the second insulating layer 52 have the sloped shape in a tapered manner (that is, a shape that slopes in the direction being displaced upward from the contact holes 54 toward the center C1 of each trench 34). When the contact holes 54 are formed, the resist 60 is removed by ashing and the like.

Next, the SiC substrate 12 is subjected to heating in N₂ atmosphere. Here, the SiC substrate 12 is heated to the temperature that is lower than the softening temperature of the first insulating layer 51 and higher than the softening temperature of the second insulating layer 52. As shown in FIG. 20, since the first insulating layer 51 does not soften, the shape of the first insulating layer 51 is hardly deformed. The second insulating layer 52 is softened, thus the front surface of the second insulating layer 52 becomes curved. Since the side surfaces of the second insulating layer 52 are sloped in tapered shape prior to the heating, the inclination angle (θ1 in FIG. 17) of the surfaces of the end portions of the second insulating layer 52 after the heating becomes extremely large. As a result, as shown in FIG. 17, the surface of the center portion 55a of the second insulating layer 52 comes to have a convex curved shape, while the surfaces of the end portions 55b of the second insulating layer 52 come to have a concave curved shape. Thereafter, when the temperature is lowered, the second insulating layer 52 hardens in the state of being curved.

Next, the source electrode 80 (that is, contact layers 80a, intermediate layer 80b, and front surface layer 80c) is formed. Since the inclination angle θ1 of the surfaces of the end portions of the second insulating layer 52 is large, the intermediate layer 80b can easily grow in the contact holes 54. Further, by curving the front surface of the second insulating layer 52, the steps between the front surface of the second insulating layer 52 and the bottom surfaces of the contact holes 54 are smoothed out. Due to this, the intermediate layer 80b is smoothed, and the front surface of the front surface layer 80c is also smoothed. According to the method of the second embodiment, the front surfaces of the intermediate layer 80b and the front surface layer 80c can further be smoothed than in the first embodiment. Further, by this method as well, a thickness necessary for the insulation resistance can be ensured by the first insulating layer 51.

Further, upon growing the AlSi layer of the intermediate layer 80b, a crystal orientation of the AlSi layer grown on the upper surface 12a of the SiC substrate 12 and a crystal orientation of the AlSi layer grown on the front surface of the second insulating layer 52 are substantially equal, whereas a crystal orientation of the AlSi layer grown on the side surfaces of the first insulating layer 51 differs from the aforementioned two crystal orientations. Due to this, a crystal interface of the AlSi layer is formed within the intermediate layer 80b. When the AlSi layer can easily be grown on the upper surface 12a of the SiC substrate 12 as in the second embodiment, the AlSi layer growing on the side surfaces of the first insulating layer 51 becomes less, as a result of which the crystal interface formed in the intermediate layer 80b becomes less. Due to this, in the second embodiment, a strength of the intermediate layer 80b improves compared to the first embodiment.

When the source electrode 80 is formed, the MOSFET of the second embodiment shown in FIG. 16 is completed by forming structures (that is, the drain region 30 and the drain electrode 84) on the lower surface 12b side using well-known methods.

Notably, in the aforementioned second embodiment, the second insulating layer 52 was etched in the isotropic etching until the first insulating layer 51 is exposed. However, the isotropic etching can be stopped at a stage where the first insulating layer 51 is not exposed. For example, the etching of the second insulating layer 52 may be carried out by conducting the isotropic etching to an intermediate portion in a thickness direction of the second insulating layer, and thereafter conducting an anisotropic etching so as to penetrate the second insulating layer and the first insulating layer.

Further, in the aforementioned embodiment, the isotropic etching is performed on the second insulating layer 52 using the resist 60 as the mask, and the anisotropic etching is performed thereafter on the first insulating layer 51 using the same resist 60 as the mask. However, so long as a wide area is etched by a preceding etching and a narrow area is etched by a following etching, the second insulating layer 52 having the curved surface with changing curvatures as in the second embodiment can be formed by softening the second insulating layer 52 after the etchings. Thus, the etching in the respective processes can freely be changed. For example, different masks may be used in the preceding etching and the following etching. Further, the employment of the isotropic etching or the anisotropic etching respectively in the preceding etching and the following etching can suitably be changed. However, according to the method of the second embodiment, since the same resist 60 can be used as the mask, the MOSFET can effectively be manufactured.

Further, in the aforementioned first and second embodiments, the MOSFET has been described, however, the technique disclosed in this description may be adapted to other semiconductor devices having a trench type gate electrode (for example, IGBT, etc.).

Further, in the aforementioned first and second embodiments, the semiconductor device having the SiC substrate 12 has been described, however, the technique disclosed in this description may be adapted to other semiconductor devices that use other semiconductor substrates such as a silicon substrate. However, in a power semiconductor device having the SiC substrate, refinement is in progress by utilizing its high voltage resistant property brought forth by a wide band gap of the SiC substrate. Due to this, in the semiconductor device having the SiC substrate, a high electric field tends to be applied to the interlayer insulating film. Due to this, it is more effective to adapt the technique disclosed in this description to a semiconductor device having the SiC substrate.

Hereinbelow, a relationship between constituent features of the aforementioned first and second embodiments and constituent features of the claims will be described. The intermediate layer 80b of the first and second embodiments is an example of an upper electrode layer of the claims. Further, the entirety of the source electrode 80 of the first and second embodiments may be regarded as an example of an upper electrode layer of the claims.

Suitable configurations of the embodiments described above will be listed below. Notably, all of the configurations listed below are useful independently.

In a method provided herein as an example, the formation of the interlayer insulating film comprises first to fourth processes. In the first process, the first insulating layer is formed so as to cover the upper surface of each of the gate electrodes and the upper surface of the semiconductor substrate. In the second process, the second insulating layer is formed on the first insulating layer. In the third process, the second insulating layer is etched in a range between each pair of the adjacent two of the trenches. In the fourth process, the contact hole is formed by etching the first insulating layer in a range within and narrower than the range in which the second insulating layer was etched.

According to this configuration, the openings of the contact holes become wider than the bottom surfaces of the contact holes after the fourth process. If the heating is performed in this state, the inclination angle of the surfaces of the end portions of the second insulating layer becomes extremely large. As a result, the surfaces of the end portions of the second insulating layer become curved surfaces that curve in the concave shape. The surface of the center portion of the second insulating layer becomes a curved surface that bulges in the convex shape. When the second insulating layer has such a shape, the surface of the upper electrode layer is further smoothed upon forming the upper electrode layer.

In a method provided herein as an example, the second insulating layer is etched by isotropic etching via a mask in the etching of the second insulating layer, and the first insulating layer is etched by anisotropic etching via the mask in the etching of the first insulating layer.

According to this configuration, the semiconductor device can effectively be manufactured, since two etching processes can be performed using the same mask.

In an semiconductor device provided herein as an example, a surface of a center portion of the second insulating layer is a convex curved surface, and the surfaces of the end portions of the second insulating layer are concave curved surfaces.

According to this configuration, the surface of the upper electrode layer is likely to be further smoothed.

The embodiments have been described in detail in the above. However, these are only examples and do not limit the claims. The technology described in the claims includes various modifications and changes of the concrete examples represented above. The technical elements explained in the present description or drawings exert technical utility independently or in combination of some of them, and the combination is not limited to one described in the claims as filed. Moreover, the technology exemplified in the present description or drawings achieves a plurality of objects at the same time, and has technical utility by achieving one of such objects.

1-5. (canceled)

6. A method of manufacturing a semiconductor device, the method comprising:
forming a plurality of trenches in an upper surface of a semiconductor substrate;
forming a gate insulating film in each of the trenches;
forming a gate electrode insulated from the semiconductor substrate by the gate insulating film in each of the trenches;
forming an interlayer insulating film including a first insulating layer and a second insulating layer, wherein the first insulating layer covers an upper surface of each of the gate electrodes and the upper surface of the semiconductor substrate, the second insulating layer is located on the first insulating layer and has a softening temperature lower than a softening temperature of the first insulating layer, and a contact hole is provided in the interlayer insulating film at a position between each pair of adjacent two of the trenches;
heating the interlayer insulating film at a temperature lower than the softening temperature of the first insulating layer and higher than the softening temperature of the second insulating layer so as to make a surface of the second insulating layer into a curved surface so that surfaces of end portions of the second insulating layer are sloping from the corresponding contact holes so as to be displaced upward toward a center of the corresponding trench, and
forming an upper electrode layer so as to cover the interlayer insulating film and the contact holes,
wherein the formation of the interlayer insulating film comprises:
forming the first insulating layer so as to cover the upper surface of each of the gate electrodes and the upper surface of the semiconductor substrate;
forming the second insulating layer on the first insulating layer;
etching the second insulating layer in a range between each pair of the adjacent two of the trenches; and
forming the contact hole by etching the first insulating layer in a range within and narrower than the range in which the second insulating layer was etched,
wherein the heating is performed so as to form a surface of a center portion of the second insulating layer into a convex curved surface, and form the surfaces of the end portions of the second insulating layer into concave surfaces.

7. The method of claim 6, wherein
the second insulating layer is etched by isotropic etching via a mask in the etching of the second insulating layer, and
the first insulating layer is etched by anisotropic etching via the mask in the etching of the first insulating layer.

8. A semiconductor device, comprising:
a semiconductor substrate;
a plurality of trenches provided in an upper surface of the semiconductor substrate;
a gate insulating film located in each of the trenches;
a gate electrode located in each of the trenches and insulated from the semiconductor substrate by the gate insulating film;
an interlayer insulating film including a first insulating layer and a second insulating layer, wherein the first insulating layer covers an upper surface of each of the gate electrodes and the upper surface of the semiconductor substrate, the second insulating layer is located on the first insulating layer and has a softening temperature lower than that of the first insulating layer, and a contact hole is provided in the interlayer insulating film at a position between each pair of adjacent two of the trenches; and
an upper electrode layer covering the interlayer insulating film and the contact holes,
wherein
an upper surface of the first insulating layer is flat,
a surface of the second insulating layer is curved,
surfaces of end portions of the second insulating layer are sloping from the corresponding contact holes so as to be displaced upward toward a center of the corresponding trench,
a surface of a center portion of the second insulating layer is a convex curved surface, and
the surfaces of the end portions of the second insulating layer are concave curved surfaces.
